(19) United States
(12) Patent Application Publication
(10) Pub. No.: US 2012/0228703 A1
(43) Pub. Date: Sep. 13, 2012

(54) SEMICONDUCTOR DEVICE AND METHOD FOR MANUFACTURING SAME

(75) Inventor: Koichi YAMAOKA, Kanagawa-ken (JP)

(73) Assignee: Kabushiki Kaisha Toshiba, Tokyo (JP)

(21) Appl. No.: 13/239,122

(22) Filed: Sep. 21, 2011

(30) Foreign Application Priority Data
Mar. 8, 2011 (JP) 2011-050057

(51) Int. Cl. H01L 29/78; H01L 21/311

(52) U.S. Cl. 257/335; 438/702; 257/E29.256; 257/E21.249

(57) ABSTRACT

According to one embodiment, a semiconductor device includes a semiconductor substrate, and an insulating member. The semiconductor substrate has a trench formed in a top surface. The insulating member is provided in the trench. A space is formed between the semiconductor substrate and the insulating member.

### CROSS-REFERENCE TO RELATED APPLICATIONS

This application is based upon and claims the benefit of priority from the prior Japanese Patent Application No. 2011-050057, filed on Mar. 8, 2011; the entire contents of which are incorporated herein by reference.

### FIELD

Embodiments described herein relate generally to a semiconductor device and a method for manufacturing the same.

### BACKGROUND

Conventionally, laterally diffused metal-oxide-semiconductor field-effect transistors (LDMOS transistors) with a source layer and a drain layer formed in an upper layer portion of a silicon substrate, and shallow trench isolation (STI) formed between the source layer and the drain layer have been developed. In LDMOS of this type, a diffusion layer is formed surrounding the STI and current flows between the source layer and the drain layer via the diffusion layer.

### BRIEF DESCRIPTION OF THE DRAWINGS

FIG. 1 is a cross-sectional view illustrating a semiconductor device according to a first embodiment;

FIG. 2 is a cross-sectional view illustrating a semiconductor device according to a comparative example;

FIGS. 3 to 7 are process cross-sectional views illustrating a method for manufacturing a semiconductor device according to a second embodiment;

FIGS. 8 to 13 are process cross-sectional views illustrating a method for manufacturing a semiconductor device according to a third embodiment.

### DETAILED DESCRIPTION

In general, according to one embodiment, a semiconductor device includes a semiconductor substrate, a first semiconductor region of a first conductivity type, a source layer of a second conductivity type, a drain layer of the second conductivity type, a second semiconductor region of the second conductivity type, an insulating member, a gate insulating film and a gate electrode. The first semiconductor region is formed on a surface of the semiconductor substrate. The source layer is formed on a surface of the first semiconductor region. The drain layer is formed on the surface of the semiconductor substrate. The second semiconductor region is formed between the source layer and the drain layer at the surface of the semiconductor substrate, and is in contact with the drain layer. The insulating member is provided in a trench formed from a top surface side in the second semiconductor region, and has a space formed between the insulating member and the semiconductor substrate. The gate insulating film is provided on a portion of the semiconductor substrate between the source layer and the insulating member. The gate electrode is provided on the gate insulating film.

In general, according to one embodiment, a semiconductor device includes a semiconductor substrate, and an insulating member. The semiconductor substrate has a trench formed in a top surface. The insulating member is provided in the trench. A space is formed between the semiconductor substrate and the insulating member.

In general, according to one embodiment, a method is disclosed for manufacturing a semiconductor device. The method can include forming a trench in a top surface of a semiconductor substrate. The method can include forming a first insulating film on inner faces of the trench. The method can include forming a second insulating film on the first insulating film. The method can include leaving a part of a portion of the first insulating film positioned below the second insulating film and removing a remaining portion of the portion by etching under conditions. An etching rate of the first insulating film is higher than an etching rate of the second insulating film under the conditions. In addition, the method can include depositing a third insulating film so as to leave as a space at least a part of a gap resulting from the removing the remaining portion.

In general, according to one embodiment, a method is disclosed for manufacturing a semiconductor device. The method can include forming a trench in a top surface of a semiconductor substrate. The method can include forming sidewalls formed from an insulating material on side faces of the trench. The method can include removing portions of the semiconductor substrate in regions directly below the sidewalls by isotropic etching of the semiconductor substrate. In addition, the method can include depositing an insulating film in the trench so as to leave as a space at least a part of a gap resulting from the removing the portions positioned in the regions directly below the sidewalls.

Various embodiments will be described hereinafter with reference to the accompanying drawings.

First, a first embodiment will be explained.

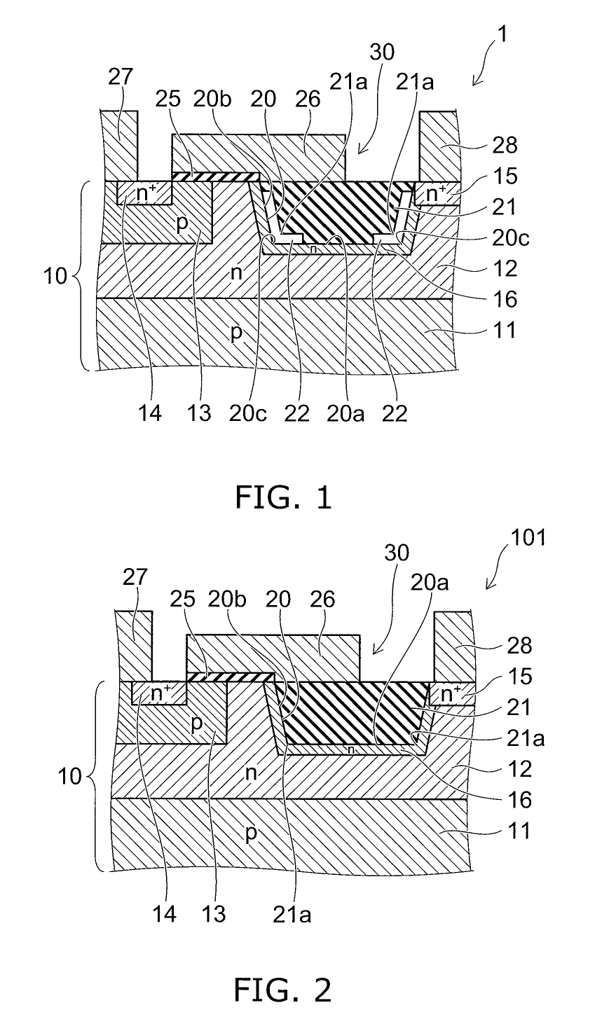

FIG. 1 is a cross-sectional view illustrating a semiconductor device according to the embodiment.

As illustrated in FIG. 1, a semiconductor device 1 according to the embodiment is a device having a laterally diffused metal-oxide-semiconductor field-effect transistor (LDMOS) 30 formed therein.

As illustrated in FIG. 1, a silicon substrate 10 is provided in the semiconductor device 1 according to the embodiment. In the silicon substrate 10, an n-type epitaxial layer 12 of n-type conductivity is provided on a p-type portion 11 of p-type conductivity. A p-type body layer 13 is formed in a portion of the upper layer portion of the n-type epitaxial layer 12, and an n⁺-type source layer 14 is formed in a portion of the upper layer portion of the p-type body layer 13. The n⁺-type source layer 14 is exposed on a top surface of the silicon substrate 10, and is positioned within the p-type body layer 13 when viewed from above. Further, an n⁺-type drain layer 15 is formed in a region that is in the upper layer portion of the n-type epitaxial layer 12 and separated from the p-type body layer 13. The p-type portion 11, the n-type epitaxial layer 12, the p-type body layer 13, the n⁺-type source layer 14 and the n⁺-type drain layer 15 are portions of the silicon substrate 10.

A trench 20 is formed between the p-type body layer 13 and the n⁺-type drain layer 15 in a top surface of the n-type epitaxial layer 12. The cross-sectional profile of the trench 20 is, for example, an upside-down trapezoidal profile in which an upper side is longer than a bottom side. Further, the trench 20 is formed to be deeper than the n⁺-type source layer 14 and the n⁺-type drain layer 15. An n-type reduced surface layer 16 is formed in a portion of the n-type epitaxial layer 12 that abuts the trench 20. Thus, a bottom face 20a and side faces 20b of the trench 20 are made of the n-type reduced surface layer 16. An effective impurity concentration of the n-type reduced surface layer 16 is higher than an effective impurity concentration of the n-type epitaxial layer 12, and lower than an effective impurity concentration of the n⁺-type source layer 14 and the n⁺-type drain layer 15. Note that “effective impurity concentration” is used to mean the impurity concentration that contributes to the conduction of the semiconductor material that is the base material and, where the material includes both impurities that are acceptors and impurities that are donors, “effective impurity concentration” is used to mean the concentration after accounting for mutual cancellation by the acceptors and donors. An end portion on the n⁺-type source layer 14 side of the n-type reduced surface layer 16 is separated from the p-type body layer 13, and an n-type epitaxial layer 12 is interposed between the n-type reduced surface layer 16 and the p-type body layer 13. On the other hand, an end portion on the n⁺-type drain layer 15 side of the n-type reduced surface layer 16 is in contact with the n⁺-type drain layer 15.

An insulating member 21 is provided in the trench 20. The insulating member 21 is formed from an insulating material such as silicon oxide. In addition, a space 22 is formed between the n-type reduced surface layer 16 and the insulating member 21. The space 22 is formed at a portion that includes a corner portion 20c formed by the bottom face 20a and the side faces 20b of the trench 20. In other words, the space 22 is formed along peripheral portions of the bottom face 20a and bottom portions of the side faces 20b. Consequently, the corner portions 20c of the trench 20 and corner portions 21a formed by the side faces and the bottom face of the insulating member 21 are separated by the space 22. In other words, the trench 20 is not completely filled by the insulating member 21 and the space 22 is left at the portion including the corner portions 20c. On the other hand, an uppermost portion of the side faces and a central portion of the bottom portion of the insulating member 21 are in contact with the n-type reduced surface layer 16.

Further, a gate insulating film 25, a gate electrode 26, a source contact 27 and a drain contact 28 are provided on the silicon substrate 10. The gate insulating film 25 is formed from an insulating material such as silicon oxide, and is arranged in a region that is directly above a region between the n⁺-type source layer 14 and the insulating member 21. The gate electrode 26 is formed from a conducting material such as polysilicon injected with an impurity, and is arranged, so as to cover the gate insulating film 25, in a region directly above the gate insulating film 25 and in a region directly above a portion on the n⁺-type source layer 14 side of the insulating member 21. The source contact 27 and the drain contact 28 are formed from a conducting material such as a metal. A bottom end of the source contact 27 is in contact with the p-type body layer 13 and the n⁺-type source layer 14, and a bottom end of the drain contact 28 is in contact with the n⁺-type drain layer 15.

The n-channel type LDMOS 30 is formed by the n-type epitaxial layer 12, the p-type body layer 13, the n⁺-type source layer 14, the n⁺-type drain layer 15, the n-type reduced surface layer 16, the insulating member 21, the gate insulating film 25 and the gate electrode 26. In the LDMOS 30, a portion in the p-type body layer 13 arranged between the n⁺-type source layer 14 and the n-type reduced surface layer 16 functions as a channel region.

In addition, in the LDMOS 30, the trench 20 is formed so as to be interposed in a current path between the n⁺-type source layer 14 and the n⁺-type drain layer 15. By providing the insulating member 21 in the trench 20, the source-drain withstand voltage can be secured. Further, the structural body in which the insulating member 21 fills the trench 20 leaving the space 22 is also provided in portions of the semiconductor device 1 other than the LDMOS 30, and functions, for example, as a device-isolating insulation film (STI).

Next, the operation of the embodiment will be explained.

In the embodiment, when a potential higher than a threshold voltage of the LDMOS 30 is applied to the gate electrode 26, an inversion layer is formed in a portion directly below the gate electrode 26 in the p-type body layer 13. As a result, the LDMOS 30 goes into an on-state, and current flows from the n⁺-type drain layer 15 to the n⁺-type source layer 14 via the inversion layer formed in the n-type reduced surface layer 16 and the p-type body layer 13. At this time, because the space 22 is formed between the insulating member 21 and the n-type reduced surface layer 16 and the corner portions 21a of the insulating member 21 are separated from the current path, there is no concentration of an electric field at the corner portions 21a. As a result, carriers such as holes or electrons resulting from hot carrier injection (HCI) are not trapped at the corner portions 21a of the insulating member 21.

Next, the effect of the embodiment will be explained.

As described above, in the embodiment, because the space 22 is formed between the insulating member 21 and the n-type reduced surface layer 16, the electric field is not concentrated at the corner portions 21a of the insulating member 21 and carriers are not trapped. Hence, there is no deterioration of the characteristics of the LDMOS 30 due to trapped carriers. Consequently, according to the embodiment, a highly reliable semiconductor device with stable LDMOS 30 characteristics can be realized.

Note that although in the embodiment, an example was described in which the space 22 was formed at peripheral portions of the bottom face 20a and the bottom portions of the side faces 20b of the trench 20, the invention is not limited to this arrangement. Provided that the space 22 is formed in at least a portion of the region between the silicon substrate 10 and the insulating member 21, the effect of suppressing the trapping of the carriers can be obtained. Note, however, that because it is particularly easy for the electric field to become concentrated at the corner portions 21a, separating the corner portions 21a from the silicon substrate 10 by the space 22 is particularly effective as a way to suppress the injection of carriers.

Next, a comparative example is described.

FIG. 2 is a cross-sectional view illustrating a semiconductor device according to the comparative example.

As illustrated in FIG. 2, a semiconductor device 101 according to the comparative example differs from the semiconductor device 1 according to the above-described first embodiment (see FIG. 1) in that the insulating member 21 fills the entire trench 20 so that the space 22 (see FIG. 1) is not formed.

In the comparative example, the corner portions 21a of the insulating member 21 are in contact with the n-type reduced surface layer 16. Hence, when the LDMOS 30 goes into an on-state and current flows between the n⁺-type source layer 14 and the n⁺-type drain layer 15, the electric field is concentrated at the corner portions 21a of the insulating member 21 and carriers, such as holes, are trapped at the corner portions 21a. As a result, the characteristics of the LDMOS 30 deteriorate. Hence, the semiconductor device 101 according to the comparative example has a lower reliability.

Next, a second embodiment will be explained.

The embodiment is an embodiment of a method for manufacturing the semiconductor device according to the above-described first embodiment. In other words, the embodiment is an embodiment of a method for manufacturing a semiconductor device that includes laterally diffused metal-oxide-semiconductor field-effect transistors (LDMOS transistors), and, more specifically, is a portion of a method for forming LDMOS transistors.

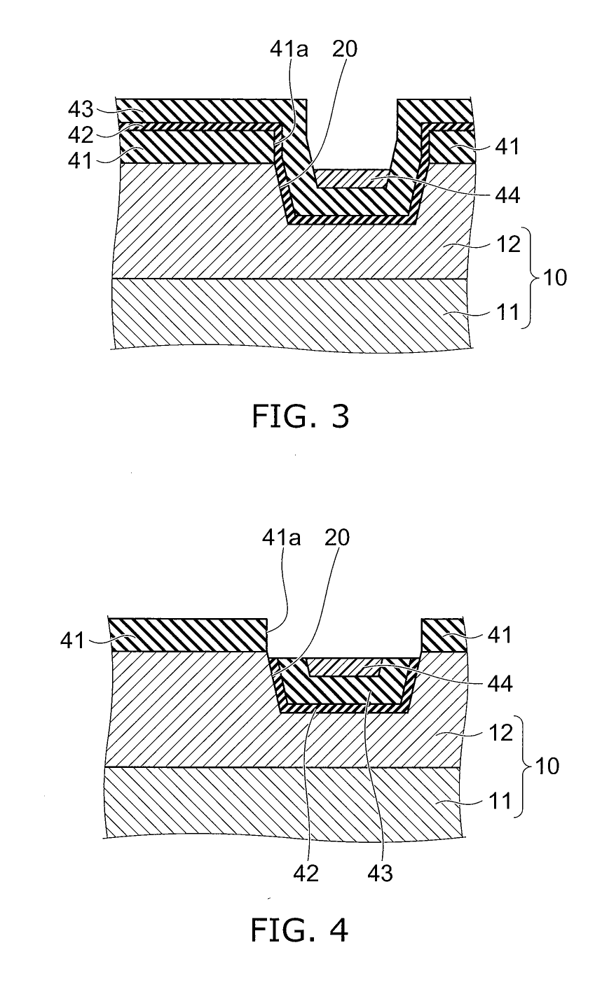

FIGS. 3 to 7 are process cross-sectional views illustrating a method for manufacturing the semiconductor device according to the embodiment.

First, as illustrated in FIG. 3, n-type silicon is epitaxially grown on a p-type silicon substrate to form the n-type epitaxial layer 12. As a result, the silicon substrate 10 having the n-type epitaxial layer 12 formed on the p-type portion 11 is fabricated. Next, a mask material 41 is formed on the silicon substrate 10. An opening 41a is formed in the mask material 41. Next, etching is performed on the silicon substrate 10 using the mask material 41 as a mask. As a result, the trench 20 is formed in a region directly below the opening 41a in an upper layer portion of the n-type epitaxial layer 12. Here the cross-sectional profile of the trench 20 is, for example, an upside-down trapezoidal profile.

Next, for example, silicon oxide with an additive of boron (Boron Silicate Glass: BSG) is deposited on the entire surface of the substrate 10 to form an insulating film 42. The insulating film 42 is also formed on inner faces of the trench 20. Next, for example, silicon oxide without added impurities (non-doped silicate glass: NSG) is deposited on the entire surface of the insulating film 42 to form an insulating film 43. The insulating film 43 is also formed on inner faces of the trench 21. The insulating film 42 is formed to be thinner than the insulating film 43 and the boron concentration of the insulating film 42 is set to be higher than the boron concentration of the insulating film 43. Note that although in the embodiment, an example was described in which the insulating film 42 was formed from BSG and the insulating film 43 was formed from NSG, the insulating films 42 and 43 may be formed from other materials. Note, however, that it is necessary to have etching selectivity between the insulating film 42 and the insulating film 43.

Next, a resist film 44 is formed on the insulating film 43 within the trench 20. Here, a total film thickness of the insulating film 42, the insulating film 43 and the resist film 44 is set so as not to exceed the depth of the trench 20. In other words, a top surface of the resist film 44 is positioned lower than a top surface of the silicon substrate 10.

Next, as illustrated in FIG. 4, the insulating film 43 and the insulating film 42 are etched by the recess process using the resist film 44 as a mask. As a result, portions of the insulating film 43 and the insulating film 42 formed higher than the top surface of the resist film 44 are removed. The portions to be removed include portions formed outside the trench 20. Thereafter, the resist film 44 is removed.

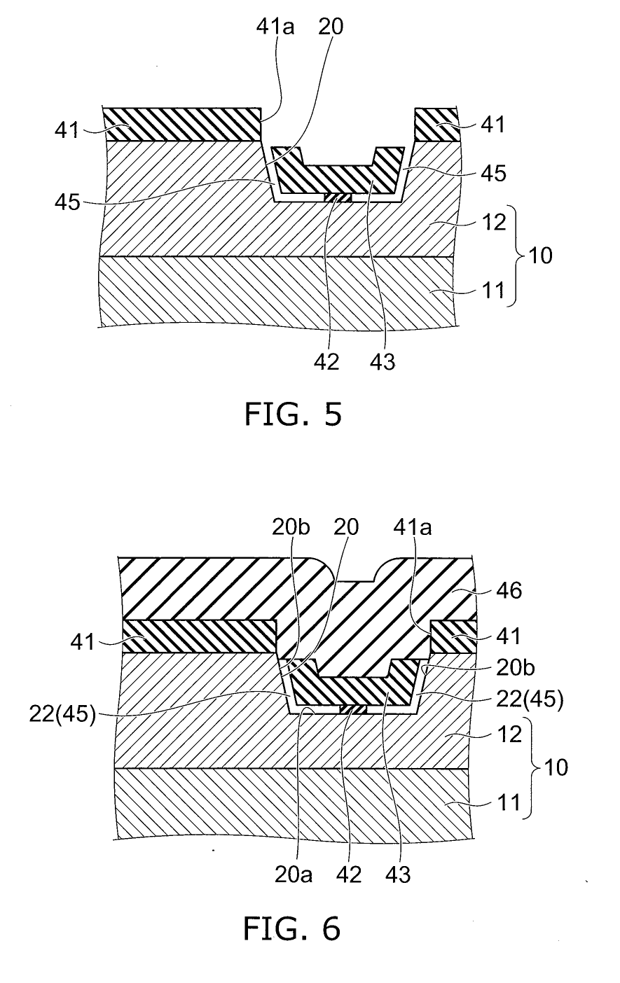

Next, as illustrated in FIG. 5, wet etching is performed on the silicon substrate 10 using an etchant. A condition of the wet etching is that an etching rate of the insulating film 42 is higher than an etching rate of the insulating film 43. In addition, the etching is stopped so that a portion of the insulating film 42 remains. Hence, a portion of the insulating film 42 positioned at a central portion of the bottom portion of the trench 20 is left while other portions of the insulating film 42 are removed. The remaining portion of the insulating film 42 supports the insulating film 43, forming a strut to prevent liftoff of the insulating film 43. Further, after removing the insulating film 42 in the trench 20, a gap 45 is formed.

Next, as illustrated in FIG. 6, an insulating material such as BSG is deposited over the entire surface of the silicon substrate 10 to form an insulating film 46. The insulating film 46 fills the internal portion of the trench 20. The deposition is performed using a method in which the level of coverage is low, such as chemical vapor deposition (CVD) or physical vapor deposition (PVD), to ensure that at least a portion of the gap 45 remains as the space 22. Note that the insulating film 46 may be formed from an insulating material other than BSG.

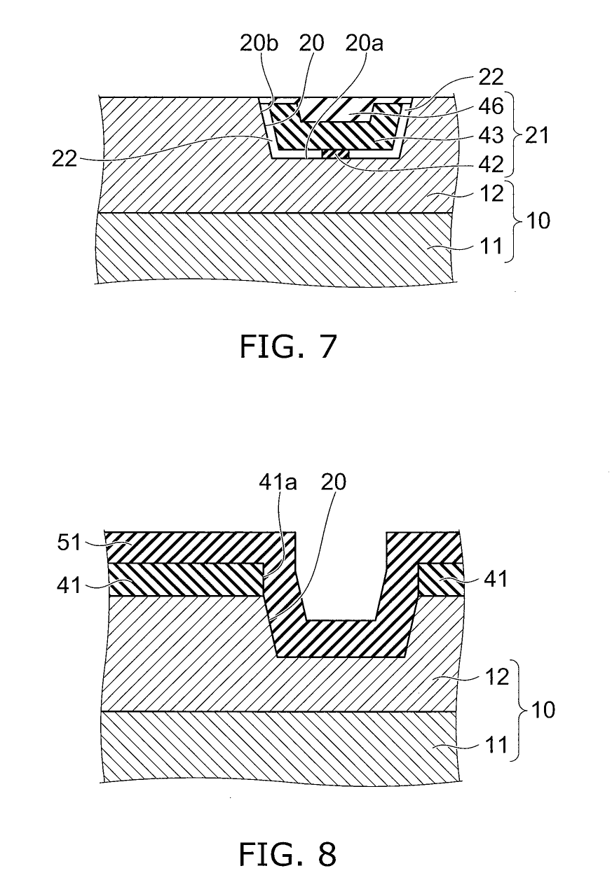

Next, as illustrated in FIG. 7, planarizing is performed to grind and remove the portions of the insulating film 46 formed on the top surface of the silicon substrate 10 and the mask material 41. As a result, the insulating member 21 formed from the insulating film 42, the insulating film 43 and the insulating film 46 is formed in the trench 20. Note that, as described above, the space 22 is formed between the insulating member 21 and the peripheral portions of the bottom face 20a and the bottom portions of the side faces 20b of the trench 20, and the corner portions 20c of the trench 20 and the corner portions 21a of the insulating member 21 are therefore separated from each other by the space 22.

The p-type body layer 13, the n⁺-type source layer 14, the n⁺-type drain layer 15 and the n-type reduced surface layer 16 illustrated in FIG. 1 are formed before forming the trench 20, after forming the trench 20 and before forming the insulating member 21, or after forming the insulating member 21.

Then, as illustrated in FIG. 1, after forming the insulating member 21, the gate insulating film 25, the gate electrode 26, the source contact 27 and the drain contact 28 are formed. By this process, the LDMOS 30 is formed and the semiconductor device 1 is manufactured.

According to the embodiment: in a process illustrated in FIG. 3, the two insulating films 42 and 43 which have etching selectivity are formed sequentially; in a process illustrated in FIG. 5, the gap 45 is formed below the insulating film 43 by selectively removing the insulating film 42 while leaving the insulating film 43; and in a process illustrated in FIG. 6, the insulating film 46 is deposited under low-coverage conditions such that the gap 45 is not completely filled, thereby forming the space 22 between the silicon substrate 10 and the insulating member 21. Hence, the semiconductor device 1 according to the above-described first embodiment can be manufactured.

Next, a third embodiment will be explained.

The embodiment is also an embodiment of a method for manufacturing the semiconductor device according to the above-described first embodiment. In other words, the embodiment is an embodiment of a method for manufacturing a semiconductor device that includes LDMOS transistors, and, more specifically, is a portion of a method for forming LDMOS transistors.

FIGS. 8 to 13 are process cross-sectional views illustrating a method for manufacturing the semiconductor device according to the embodiment.

First, as illustrated in FIG. 8, the silicon substrate 10 having the n-type epitaxial layer 12 formed on the p-type portion 11 is prepared. Next, the mask material 41 with the opening 41a formed therein is formed on the silicon substrate 10. Next, etching is performed on the silicon substrate 10 using the mask material 41 as a mask. As a result, the trench 20 is formed in a region directly below the opening 41a in an upper layer portion of the n-type epitaxial layer 12. Next, an insulating material such as silicon oxide is deposited over the entire surface of the silicon substrate 10 to form an insulating film 51. The insulating film 51 is also formed on inner faces of the trench 20.

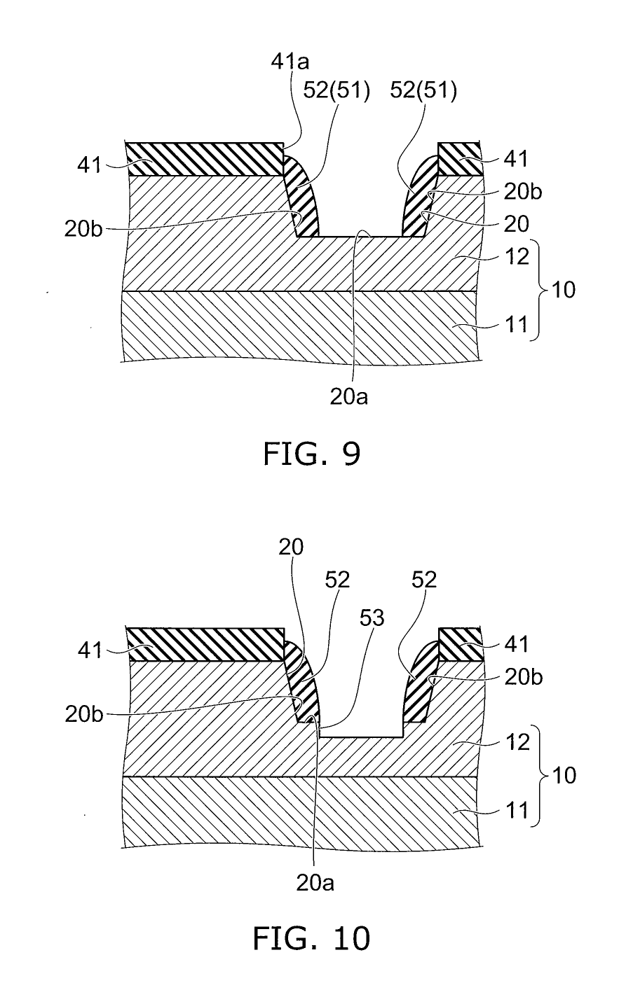

Next, as illustrated in FIG. 9, the insulating film 51 is etched back by performing anisotropic etching. As a result, the insulating film 51 is removed from the bottom face 20a of the trench 20 and a top surface of the mask material 41, and allowed to remain on the side faces 20 of the trench 20 only. Hence, sidewalls 52 formed from, for example, silicon oxide are formed on the side faces 20b of the trench 20.

Next, as illustrated in FIG. 10, the silicon substrate 10 is etched using the sidewalls 52 as a mask. As a result, a recess 53 is formed in a region of the n-type epitaxial layer 12 not covered by the sidewalls 52 at the bottom face 20a of the trench 20.

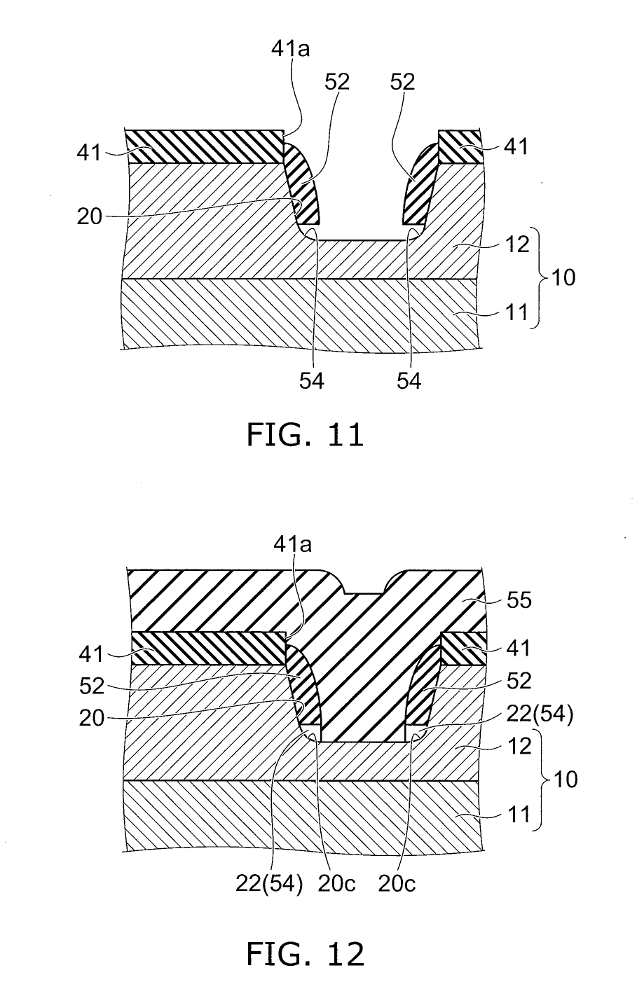

Next, as illustrated in FIG. 11, isotropic etching such as chemical dry etching (CDE) is performed on the silicon substrate 10. As a result, a portion positioned in the regions directly below the sidewalls 52 in the n-type epitaxial layer 12 is removed via the recess 53 (see FIG. 10) to form a gap 54.

Next, as illustrated in FIG. 12, an insulating film 55 is formed by depositing an insulating material such as silicon oxide over the entire surface of the silicon substrate 10. The insulating film 55 fills the internal portion of the trench 20 including the sidewalls 52. Note however, that the deposition is performed under low-coverage conditions such that at least a portion of the gap 54 is left as the space 22.

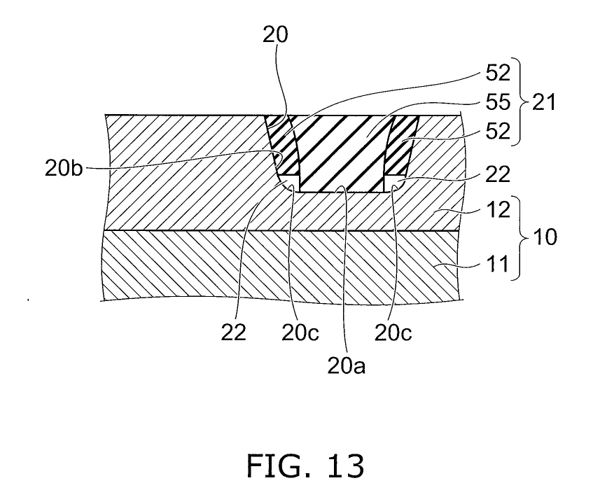

Next, as illustrated in FIG. 13, planarizing is performed to grind and remove the portions of the insulating film 55 deposited on the top surface of the silicon substrate 10 and the mask material 41. As a result, the insulating member 21 formed from the sidewalls 52 and the insulating film 55 is formed in the trench 20. Note that, as described above, the space 22 is formed between the insulating member 21 and the peripheral portions of the bottom face 20a and the bottom portions of the side faces 20b of the trench 20.

The p-type body layer 13, the n⁺-type source layer 14, the n⁺-type drain layer 15 and the n-type reduced surface layer 16 illustrated in FIG. 1 are, as in the above-described second embodiment, formed before forming the trench 20, after forming the trench 20 and before forming the insulating member 21, or after forming the insulating member 21.

Then, as illustrated in FIG. 1, after forming the insulating member 21, the gate insulating film 25, the gate electrode 26, the source contact 27 and the drain contact 28 are formed. By this process, the LDMOS 30 is fabricated and the semiconductor device 1 is manufactured.

According to the embodiment: in a process illustrated in FIG. 9, the sidewalls 52 are formed on the side faces 20b of the trench 20; in a process illustrated in FIG. 10, the recess 53 is formed by further deepening the bottom face 20a of the trench 20 using the sidewalls 52 as a mask; in a process illustrated in FIG. 11, isotropic etching is performed to form the gap 54 via the recess 53; and in a process illustrated in FIG. 12, an insulating material is deposited under low-coverage conditions to form the insulating film 55 such that the gap 54 is not completely filled, thereby forming the space 22 between the silicon substrate 10 and the insulating member 21. Hence, according to the embodiment, the semiconductor device 1 according to the above-described first embodiment can also be manufactured.

Note that although in the embodiment, an example was described in which the insulating films 51 and 55 were formed from silicon oxide, the invention is not limited to this.

According to the embodiments described above, it is possible to realize a highly reliable semiconductor device and manufacturing method for the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. The above embodiments can be practiced in combination with each other.

What is claimed is:

1. A semiconductor device comprising:
a semiconductor substrate with a trench formed in a top surface; and
an insulating member provided in the trench,
a space being formed between the semiconductor substrate and the insulating member.

2. The device according to claim 1, further comprising: a first semiconductor region of a first conductivity type formed on a surface of the semiconductor substrate;
a source layer of a second conductivity type formed on a surface of the first semiconductor region;
a drain layer of the second conductivity type formed on the surface of the semiconductor substrate;
a second semiconductor region of the second conductivity type formed between the source layer and the drain layer at the surface of the semiconductor substrate, the trench being formed in the second semiconductor region, and in contact with the drain layer;
an insulating member provided in a trench formed from a top surface side in the second semiconductor region, having a space formed between the insulating member and the semiconductor substrate;
a gate insulating film provided on a portion of the semiconductor substrate between the source layer and the insulating member; and
a gate electrode provided on the gate insulating film.

3. The device according to claim 2, wherein the space is formed at a portion including a corner portion formed by a bottom face and a side face of the trench.

4. The device according to claim 2, wherein a central portion of the bottom face of the trench is in contact with the insulating member.

5. The device according to claim 2, wherein the semiconductor substrate is formed from silicon and the insulating member is formed from silicon oxide.

6. The device according to claim 1, wherein the space is formed at a portion including a corner portion formed by a bottom face and a side face of the trench.

7. The device according to claim 1, wherein a central portion of the bottom face of the trench is in contact with the insulating member.

8. The device according to claim 1, wherein a source layer and a drain layer are formed in regions of the semiconductor substrate, the regions sandwich the insulating member.

9. The device according to claim 8, wherein an impurity diffused layer is formed in a portion of the semiconductor substrate abutting the trench, a conductivity type of the impurity diffused layer is same as a conductivity type of the source layer and the drain layer.

10. The device according to claim 1, wherein the semiconductor substrate is formed from silicon and the insulating member is formed from silicon oxide.

11. A method for manufacturing a semiconductor device comprising:
forming a trench in a top surface of a semiconductor substrate;
forming a first insulating film on inner faces of the trench;
forming a second insulating film on the first insulating film;
leaving a part of a portion of the first insulating film positioned below the second insulating film and removing a remaining portion of the portion by etching under conditions, an etching rate of the first insulating film being higher than an etching rate of the second insulating film under the conditions; and
depositing a third insulating film so as to leave as a space at least a part of a gap resulting from the removing the remaining portion.

12. The method according to claim 11, wherein
the first insulating film and the second insulating film are formed from silicon oxide, and
a boron concentration of the first insulating film is set higher than a boron concentration of the second insulating film.

13. The method according to claim 11, further comprising:
forming a resist film on the second insulating film within the trench; and
removing a portion of the first insulating film and the second insulating film formed outside the trench by etching using the resist film as a mask.

14. The method according to claim 11, wherein the method is a method for manufacturing a semiconductor device including a laterally diffused metal-oxide-semiconductor field-effect transistor.

15. A method for manufacturing a semiconductor device comprising:
forming a trench in a top surface of a semiconductor substrate;
forming sidewalls formed from an insulating material on side faces of the trench;
removing portions of the semiconductor substrate in regions directly below the sidewalls by isotropic etching of the semiconductor substrate; and
depositing an insulating film in the trench so as to leave as a space at least a part of a gap resulting from the removing the portions positioned in the regions directly below the sidewalls.

16. The method according to claim 15, further comprising: before performing the isotropic etching, forming a recess in a region not covered by the sidewalls at a bottom face of the trench by etching the semiconductor substrate using the sidewalls as a mask.

17. The method according to claim 15, wherein
the forming the sidewalls includes:
forming another insulating film on inner faces of the trench; and
performing anisotropic etching on the another insulating film.

18. The method according to claim 15, wherein the isotropic etching is chemical dry etching.

19. The method according to claim 15, further comprising: removing a portion of the insulating film deposited on the top surface of the semiconductor substrate by performing a planarizing process.

20. The method according to claim 15, wherein the method is a method for manufacturing a semiconductor device including a laterally diffused metal-oxide-semiconductor field-effect transistor.
